(19) United States
(12) Patent Application Publication
(10) Pub. No.: US 2013/0057793 A1
(43) Pub. Date: Mar. 7, 2013

(54) THIN-FILM TRANSISTOR SUBSTRATE AND LIQUID-CRYSTAL DISPLAY DEVICE PROVIDED WITH THE SAME

(71) Applicant: Seiichi Uchida, Osaka (JP)

(72) Inventor: Seiichi Uchida, Osaka (JP)

(73) Assignee: SHARP KABUSHIKI KAISHA, Osaka (JP)

(21) Appl. No.: 13/697,721

(22) PCT Filed: Feb. 1, 2011
(86) PCT No.: PCT/JP2011/000555

§ 371 Date: Nov. 13, 2012

(30) Foreign Application Priority Data
May 14, 2010 (JP) 2010-111869

(51) Int. Cl. H01L 27/12; G02F 1/136

(52) U.S. Cl. 349/42; 257/43; 257/E27.112

(57) ABSTRACT

In each pixel, an insulating film covering each oxide semiconductor layer is placed between an upper electrode of a storage capacitance element and two source wiring lines that have the upper electrode therebetween. The upper electrode is formed of a conductor layer portion that extends from the oxide semiconductor layer and that has a low resistance, and is thereby integrally formed with the oxide semiconductor layer. Both of the source wiring lines are provided on the insulating film and are connected to the oxide semiconductor layer through contact holes formed in the insulating film.

### TECHNICAL FIELD

The present invention relates to a thin-film transistor (hereinafter referred to as TFT) substrate and to a liquid crystal display device provided with the same, and more particularly, to a TFT substrate having TFTs that are provided with semiconductor layers made of oxide semiconductor and to a liquid crystal display device provided with the same.

### BACKGROUND ART

A conventional TFT substrate for a liquid crystal display device is provided with a plurality of gate wiring lines that extend in parallel with each other, a plurality of source wiring lines that extend in parallel with each other so as to intersect with the respective gate wiring lines, TFTs disposed on respective intersections of the respective gate wiring lines and the respective source wiring lines, an interlayer insulating film that covers the respective TFTs, and a plurality of pixel electrodes arranged in a matrix on the interlayer insulating film. The plurality of pixel electrodes are disposed on respective pixels that are bordered by the gate wiring lines and the source wiring lines.

A typical bottom-gate TFT is provided with a gate electrode connected to a gate wiring line, a gate insulating film that covers the gate electrode, a semiconductor layer disposed on the gate insulating film so as to overlap the gate electrode, and a source electrode and a drain electrode disposed on the gate insulating film so as to overlap the semiconductor layer, being separated from each other, for example. The source electrode is integrally formed with the source wiring line. The drain electrode is connected to the pixel electrode through a contact hole formed in the interlayer insulating film.

The above TFT substrate is further provided with storage capacitance elements disposed in the respective pixels for storing a potential of the pixel electrodes while the TFTs are turned OFF. Each of the respective storage capacitance elements has a lower electrode and an upper electrode facing each other and having a gate insulating film as a dielectric layer interposed therebetween. The respective lower electrodes are formed of part of auxiliary capacitance wiring lines that extend along the respective gate wiring lines. The respective upper electrodes protrude from the respective drain electrodes and are integrally formed with the respective drain electrodes.

For a recent TFT substrate, instead of a conventional TFT that is provided with a semiconductor layer made of amorphous silicon, a TFT that is provided with a semiconductor layer made of oxide semiconductor and that has excellent characteristics such as high mobility, high reliability, and a low OFF current has been proposed.

Patent Document 1 discloses a TFT substrate having such TFTs that are provided with oxide semiconductor layers. This TFT substrate is formed as follows. In forming the oxide semiconductor layer of the respective TFTs by patterning the oxide semiconductor film by photolithography, the oxide semiconductor layer is left on areas where source wiring lines, source electrodes, drain electrodes, and pixel electrodes are to be formed. Next, the oxide semiconductor layer on the areas where these wiring lines and electrodes are to be formed is irradiated with laser or the like such that resistance thereof is reduced. This way, the source wiring lines, the source electrodes, the drain electrodes, and the pixel electrodes are integrally formed with the extended oxide semiconductor layer of the respective TFTs. Further, upper electrodes of respective storage capacitance elements are formed of part of the respective pixel electrodes.

### RELATED ART DOCUMENT

### Patent Document

Patent Document 1: Japanese Patent Application Laid-Open Publication No. 2009-99887

### SUMMARY OF THE INVENTION

### Problems to be Solved by the Invention

FIG. 21 is a schematic plan view showing a configuration of one pixel of the conventional TFT substrate.

In the conventional TFT substrate described above, because an upper electrode 102 of respective storage capacitance elements 100 and respective source wiring lines 104 are formed in the same layer as shown in FIG. 21, it is required to provide relatively wide margins between the upper electrode 102 and the two source wiring lines 104 that sandwich the upper electrode 102 such that the upper electrode 102 and the source wiring lines 104 do not make contact with each other even when the upper electrode 102 and the source wiring lines 104 are misaligned. Because of this, the upper electrode 102 cannot be formed larger toward the source wiring lines 104 along a storage capacitance wiring line 106, but has to be formed larger toward gate wiring lines 108. This makes it impossible to use a portion of the storage capacitance wiring lines 106 near the source wiring lines 104 as the lower electrode 110. Consequently, the upper electrode 102 and the lower electrode 110 need to be formed large to obtain an area where the upper electrode 102 and the lower electrode 110 face each other, and therefore, an aperture ratio of the pixel is decreased. Further, because an area between the storage capacitance element 100 and the gate wiring line 108 shown in the upper side of FIG. 21 becomes smaller, a degree of freedom in circuit design is lowered when having various circuits, such as photosensor circuits and pixel memory circuits, built in the respective pixels. This problem occurs also in the TFT substrate described in Patent Document 1 in which the source wiring lines, the source electrodes, the drain electrodes, and the pixel electrodes are respectively formed integrally with the oxide semiconductor layer of the respective TFTs.

The present invention was made in view of such problems, and aims at achieving TFTs having excellent characteristics by using oxide semiconductor, and at improving an aperture ratio of respective pixels, thereby increasing a degree of freedom in circuit design.

### Means for Solving the Problems

In order to achieve the above objects, in the present invention, a semiconductor layer of each TFT is made of oxide semiconductor, and an upper electrode of each storage capacitance element and two source wiring lines that have the upper electrode therebetween are separately formed in respective upper and lower layers through an insulating film, by taking advantage of characteristics of the oxide semiconductor layer.

Specifically, the present invention relates to a TFT substrate and a liquid crystal display device provided with the same. The TFT substrate is provided with: a plurality of gate wiring lines that extend in parallel with each other; storage capacitance wiring lines that are provided to the respective gate wiring lines and that extend along the respective gate wiring lines; a plurality of source wiring lines that extend in parallel with each other so as to intersect with the respective gate wiring lines and the respective storage capacitance wiring lines; and a TFT, a storage capacitance element, and a pixel electrode provided for each of intersections of the respective gate wiring lines and the respective source wiring lines, wherein a plurality of pixels, each of which includes the TFT, the storage capacitance element, and the pixel electrode, are defined by the respective gate wiring lines and the respective source wiring lines. In each of the pixels, the TFT is provided with: a gate electrode that is connected to the gate wiring line; a gate insulating film that covers the gate electrode; an oxide semiconductor layer that overlaps the gate electrode through the gate insulating film; a source electrode that is connected to one side of the oxide semiconductor layer and that is connected to the source wiring line; and a drain electrode that is connected to the other side of the oxide semiconductor layer and to the pixel electrode, the drain electrode being separated from the source electrode. The storage capacitance element has: a lower electrode that is connected to the storage capacitance wiring line and that is covered by the gate insulating film; a dielectric layer that is made of a portion of the gate insulating film corresponding to the lower electrode; and an upper electrode that is extended from the drain electrode and that is disposed between the source wiring lines adjacent to each other, the upper electrode overlapping the lower electrode through the dielectric layer. The present invention provides the following solutions for the TFT substrate having the above configuration and for the liquid crystal display device provided with the same.

That is, a first aspect of the present invention is the TFT substrate, wherein, in each of the pixels, an insulating film that covers the oxide semiconductor layer is disposed between the upper electrode of the storage capacitance element and a pair of source wiring lines that has the upper electrode therebetween, and one of the upper electrode and the pair of source wiring lines is formed of a conductor layer portion that is extended from the oxide semiconductor layer and that has a lowered resistance, and is thereby integrally formed with the oxide semiconductor layer and the other of the upper electrode and the pair of source wiring lines is formed on the insulating film, and is connected to the oxide semiconductor layer through a contact hole formed in the insulating film.

A second aspect of the present invention is the TFT substrate of the first aspect of the present invention, wherein, in each of the pixels, the upper electrode is led out to an area corresponding to the lower electrode through the drain electrode and the local wiring line section that are formed of a conductor layer portion extended from the oxide semiconductor layer, the conductor layer portion having a lowered resistance in a same manner as the upper electrode, and the pair of source wiring lines are disposed on the insulating film, and wherein the respective oxide semiconductor layers, the respective local wiring line sections, and the respective upper electrodes are transparent.

A third aspect of the present invention is the TFT substrate of the second aspect of the present invention, wherein the respective TFTs are covered by an interlayer insulating film, and wherein each of the pixel electrodes is formed on the interlayer insulating film so as to overlap the TFT, and is electrically connected to the drain electrode through a contact hole formed in the interlayer insulating film and in the insulating film.

A fourth aspect of the present invention is the TFT substrate of any one of the first to third aspects of the present invention, wherein the respective oxide semiconductor layers are formed of indium gallium zinc oxide-based metal oxide.

A fifth aspect of the present invention is a liquid crystal display device provided with the TFT substrate of any one of the first to fourth aspects of the present invention; an opposite substrate disposed so as to face the TFT substrate; and a liquid crystal layer disposed between the TFT substrate and the opposite substrate.

### Effects

Next, effects of the present invention will be described.

According to the first aspect of the present invention, one element out of the upper electrode of each storage capacitance element and the two source wiring lines that sandwich the upper electrode is formed of a conductor layer portion that is extended from the oxide semiconductor layer for the TFT and that has a lowered resistance, and is thereby integrally formed with the oxide semiconductor layer. The other element out of the upper electrode and the two source wiring lines is formed on the insulating film that covers the oxide semiconductor layer. When the upper electrode and the two source wiring lines that sandwich the upper electrode are separately formed in the respective upper and lower layers having the insulating film interposed therebetween, a margin does not need to be made between the upper electrode and the respective source wiring lines. This makes it possible to form the upper electrode larger toward the respective source wiring lines. As a result, a portion of the storage capacitance wiring lines near the source wiring lines can be utilized as the lower electrode. Therefore, a large area can be secured for the upper electrode and the lower electrode to face each other along the storage capacitance wiring lines, and portions of the respective electrodes on the side closer to the gate wiring line can be made smaller. This way, the aperture ratio of the respective pixels is improved, and the area between the storage capacitance element and the gate wiring line can be designed to be larger. Consequently, TFTs having the excellent characteristics can be achieved by using the oxide semiconductor, and also, the aperture ratio of the respective pixels is improved, thereby increasing the degree of freedom in circuit design.

According to the second aspect of the present invention, the oxide semiconductor layers and the local wiring line sections in the respective pixels are transparent. Therefore, light can be transmitted through the areas where the oxide semiconductor layers and the local wiring line sections are formed, thereby further increasing the aperture ratio of the pixels.

According to the third aspect of the present invention, the respective pixel electrodes are formed also on the corresponding TFTs. In this pixel configuration having the pixel electrodes arranged on the TFTs as described above, when applying the present invention to a liquid crystal display device, for example, a voltage is applied to a liquid crystal layer on areas where the TFTs of the respective pixels are formed. Therefore, the areas in the respective pixels where the TFTs are formed can be utilized for display, thereby improving a display quality.

According to the fourth aspect of the present invention, the respective TFTs can specifically obtain excellent characteristics such as high mobility, high reliability, and a low OFF current.

According to the fifth aspect of the present invention, the TFT substrate according to the first to fourth aspects of the present invention has excellent characteristics of achieving the TFTs with good characteristics by using the oxide semiconductor layer and of achieving a higher degree of freedom in circuit design by increasing the aperture ratio of the pixels. Therefore, a high-function display device can be achieved by having various circuits such as photosensor circuits and the pixel memory circuits built in the respective pixels.

### Effects of the Invention

According to the present invention, the semiconductor layer of each TFT is made of the oxide semiconductor, and the upper electrode of each storage capacitance element and the two source wiring lines that sandwich the upper electrode are separately formed in respective upper and lower layers having the insulting film interposed therebetween, by taking advantage of characteristics of the oxide semiconductor layer. Therefore, it becomes possible to achieve TFTs having excellent characteristics by using the oxide semiconductor layer, and to improve an aperture ratio of the respective pixels, thereby increasing a degree of freedom in circuit design.

### BRIEF DESCRIPTION OF THE DRAWINGS

FIG. 1 is a schematic plan view showing a liquid crystal display device of an embodiment.

FIG. 2 is a cross-sectional view of the liquid crystal display device along the line II-II in

FIG. 1.

FIG. 3 is a schematic plan view showing a structure of one pixel in a TFT substrate.

FIG. 4 is a cross-sectional view of the liquid crystal display device along the line IV-IV in FIG. 3.

FIG. 5 is a cross-sectional view of the liquid crystal display device along the line V-V in

FIG. 3.

FIG. 6 is a cross-sectional view of the liquid crystal display device along the line VI-VI in FIG. 3.

FIG. 7 shows a state in which a gate insulating film is formed in a TFT substrate manufacturing process. FIGS. 7(a) and 7(b) are cross-sectional views respectively showing a portion that corresponds to FIG. 4 and a portion that corresponds to FIG. 5.

FIG. 8 shows a state in which an oxide semiconductor film is deposited in the TFT substrate manufacturing process. FIGS. 8(a) and 8(b) are cross-sectional views respectively showing a portion that corresponds to FIG. 4 and a portion that corresponds to FIG. 5.

FIG. 9 shows a state in which a resist pattern is formed on the oxide semiconductor film in the TFT substrate manufacturing process. FIGS. 9(a) and 9(b) are cross-sectional views respectively showing a portion that corresponds to FIG. 4 and a portion that corresponds to FIG. 5.

FIG. 10 shows a state in which the oxide semiconductor film is patterned in the TFT substrate manufacturing process. FIGS. 10(a) and 10(b) are cross-sectional views respectively showing a portion that corresponds to FIG. 4 and a portion that corresponds to FIG. 5.

FIG. 11 shows a state in which a portion of the oxide semiconductor layer exposed from the resist pattern is processed so as to have a lowered resistance in the TFT substrate manufacturing process. FIGS. 11(a) and 11(b) are cross-sectional views respectively showing a portion that corresponds to FIG. 4 and a portion that corresponds to FIG. 5.

FIG. 12 shows a state in which a source wiring line and a source electrode are formed in the TFT substrate manufacturing process. FIGS. 12(a) and 12(b) are cross-sectional views respectively showing a portion that corresponds to FIG. 4 and a portion that corresponds to FIG. 5.

FIG. 13 shows a state in which a pixel electrode is formed in the TFT substrate manufacturing process. FIGS. 13(a) and 13(b) are cross-sectional views respectively showing a portion that corresponds to FIG. 4 and a portion that corresponds to FIG. 5.

FIG. 14 is a schematic plan view showing a structure of one pixel in a TFT substrate in a modification example.

FIG. 15 is a cross-sectional view of the liquid crystal display device along the line XV-XV in FIG. 14.

FIG. 16 is a cross-sectional view of the liquid crystal display device along the line XVI-XVI in FIG. 14.

FIG. 17 is a cross-sectional view of the liquid crystal display device along the line XVII-XVII in FIG. 14.

FIG. 18 is a cross-sectional view of the liquid crystal display device along the line XVIII-XVIII in FIG. 14.

FIG. 19 is a schematic plan view showing a structure of one pixel in a TFT substrate of another embodiment.

FIG. 20 is a schematic plan view showing a structure of one pixel in a conventional TFT substrate having a photosensor circuit built in each pixel.

FIG. 21 is a schematic plan view showing a structure of one pixel in the conventional TFT substrate.

### DETAILED DESCRIPTION OF EMBODIMENTS

Embodiments of the present invention will be described below in detail with reference to figures. The present invention is not limited to the respective embodiments below.

### Embodiments of the Present Invention

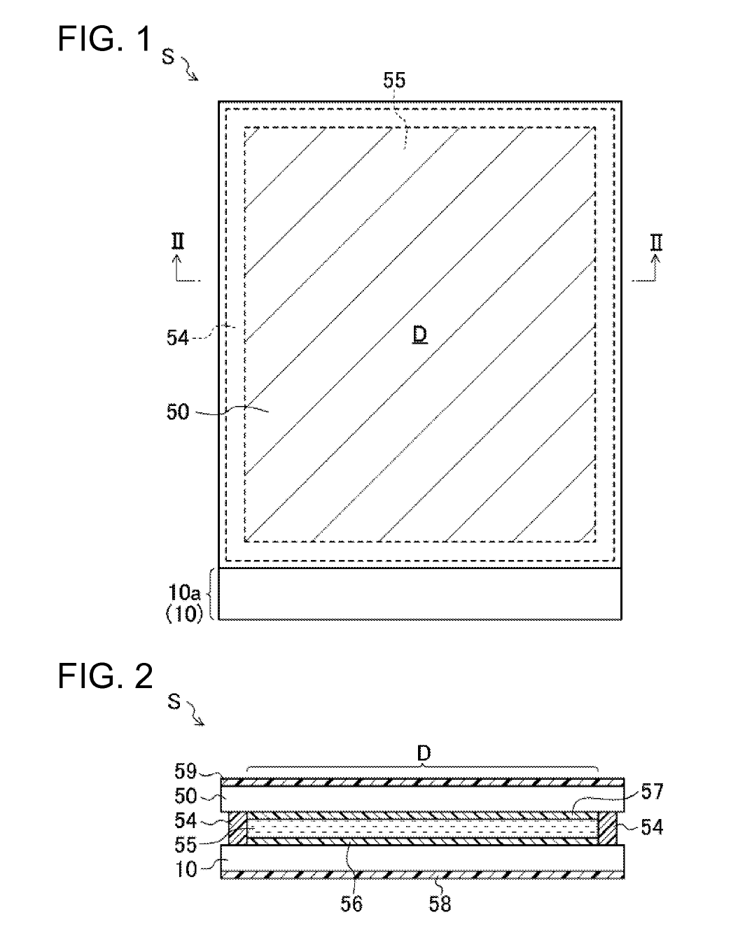

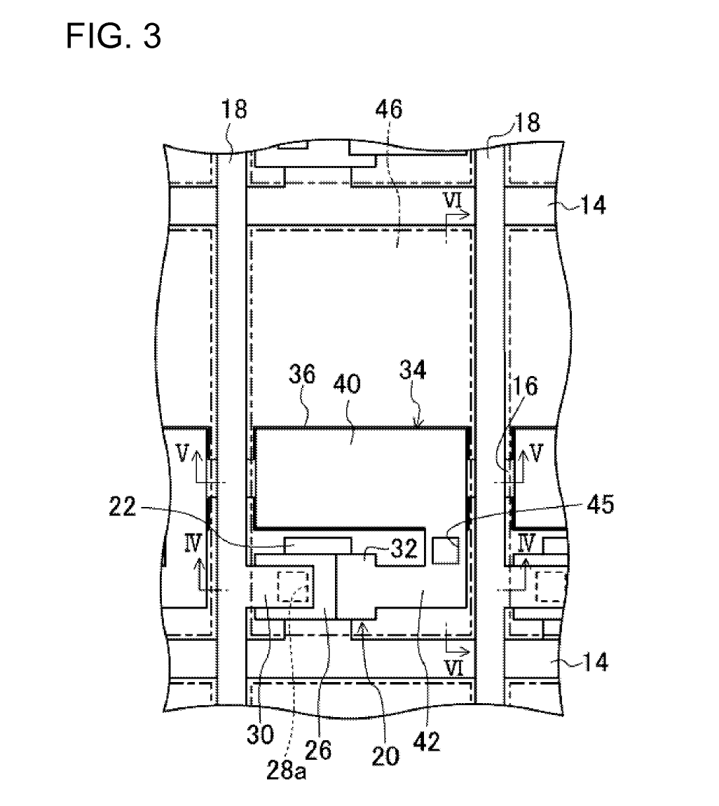

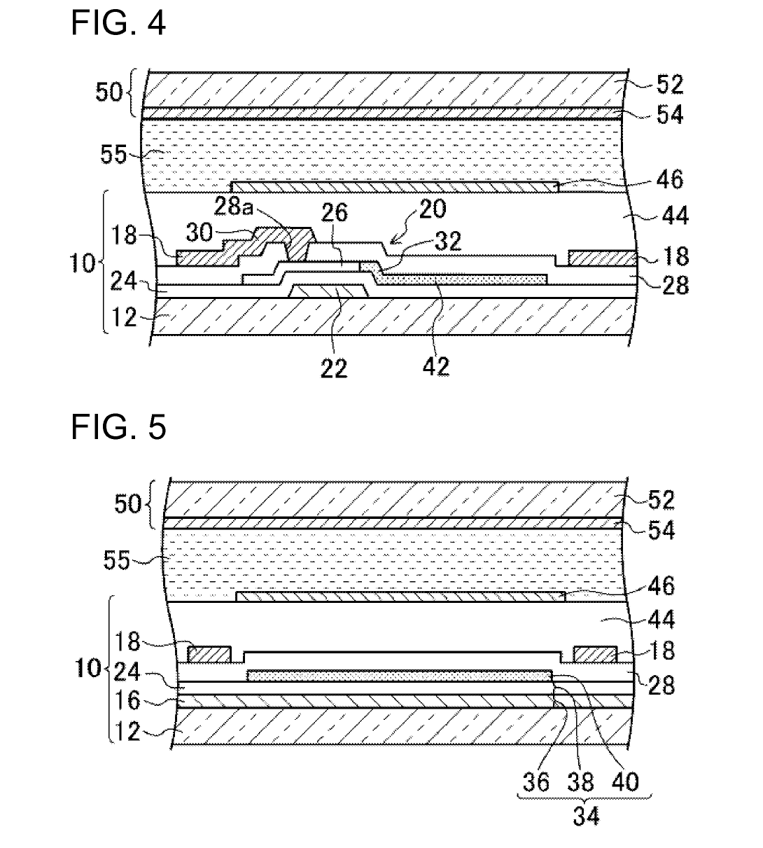

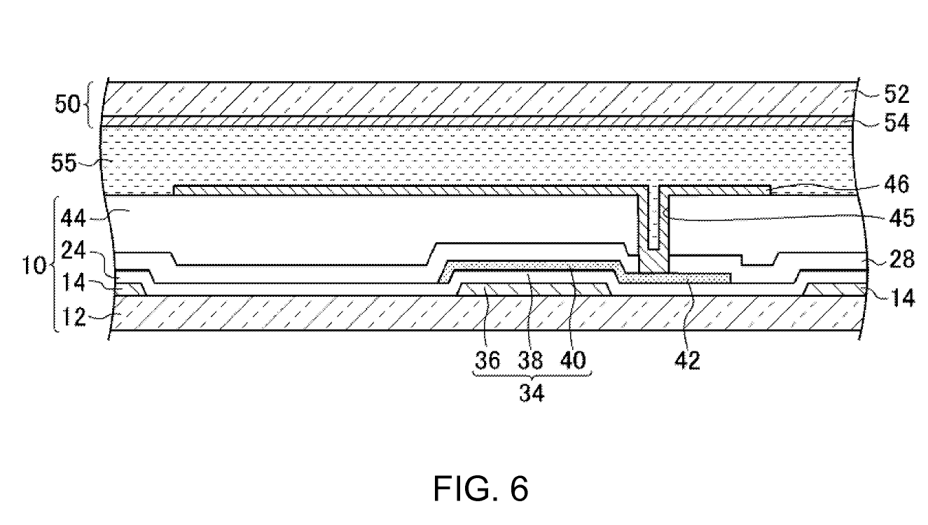

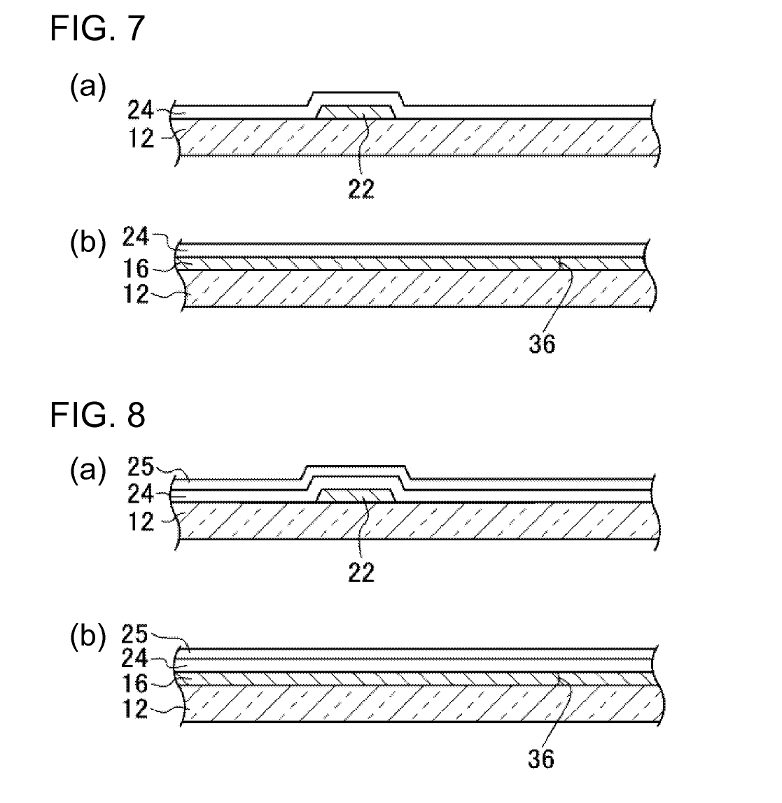

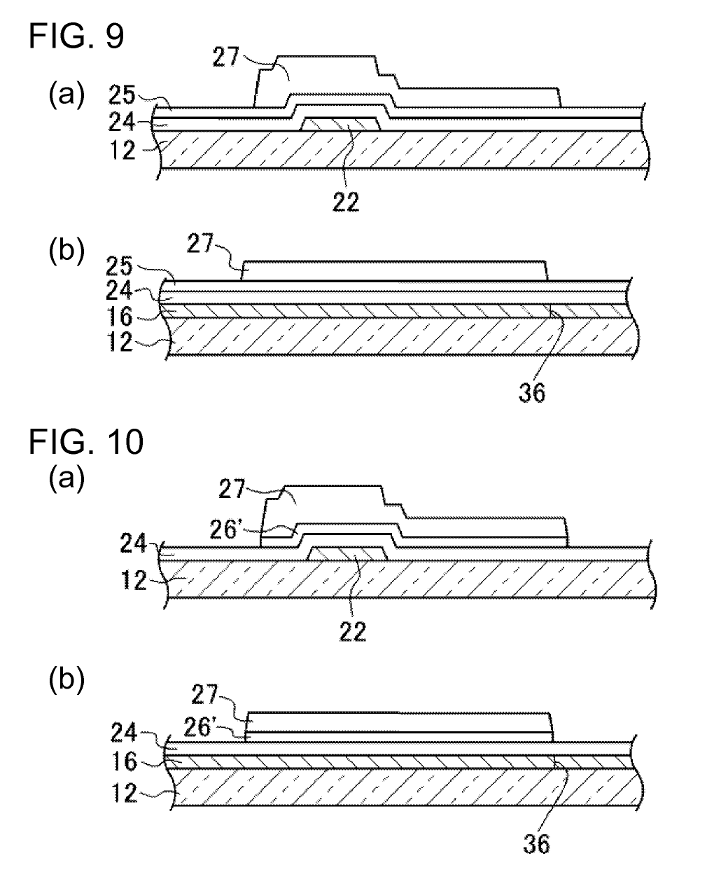

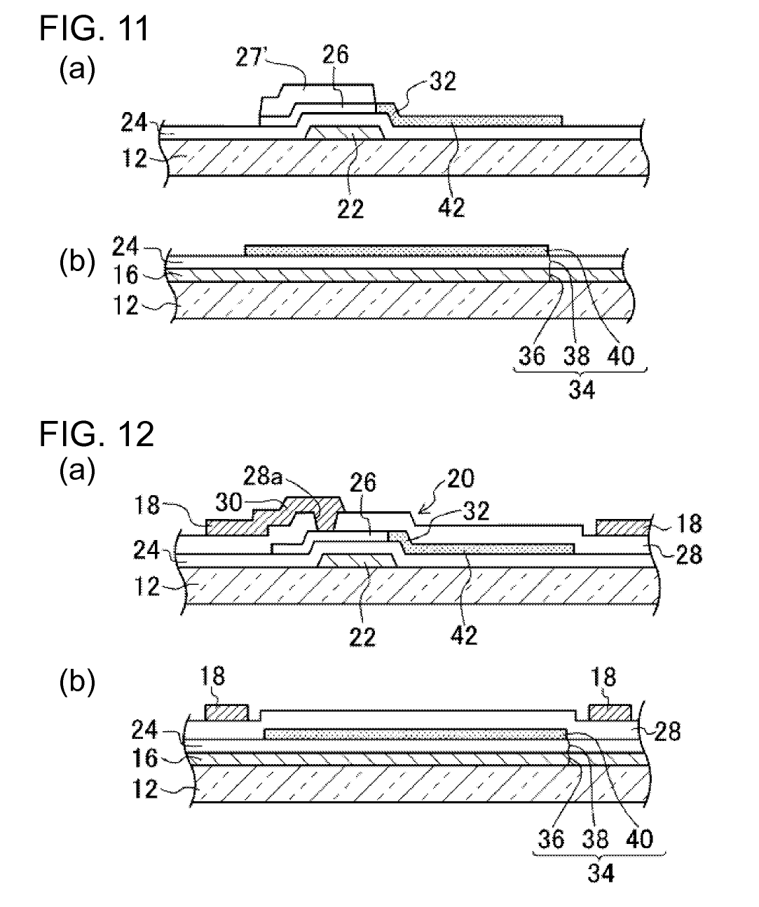

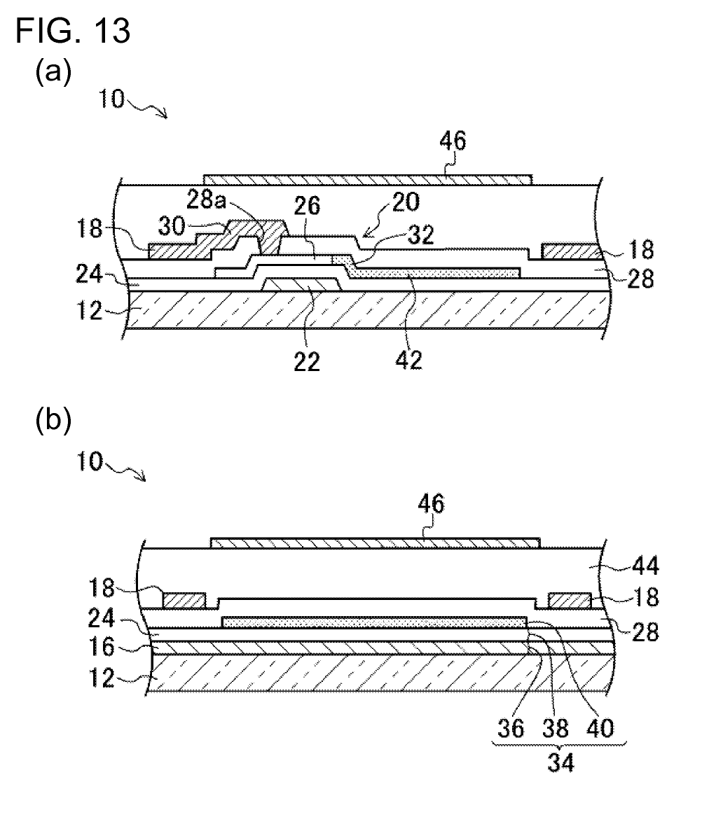

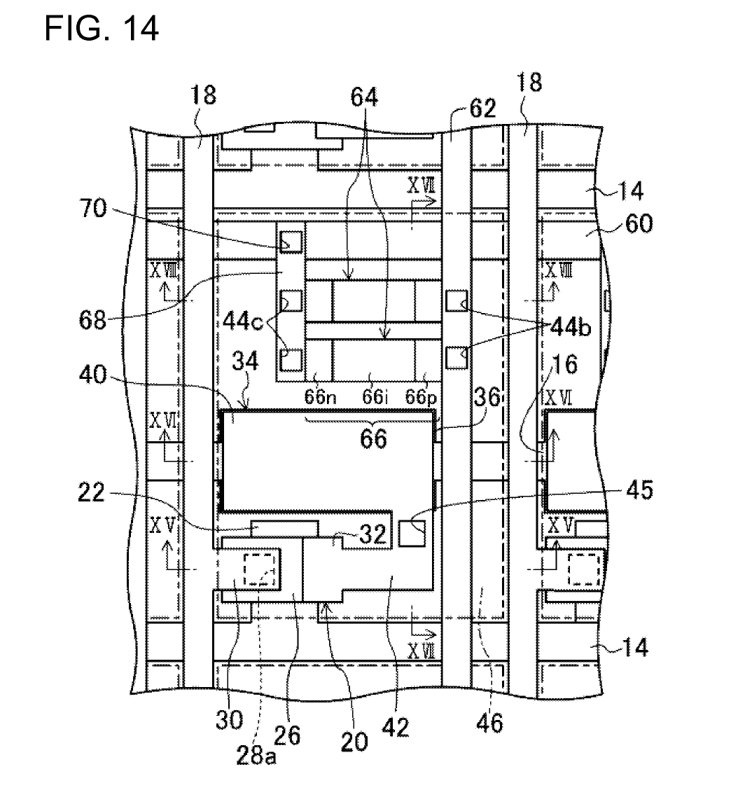

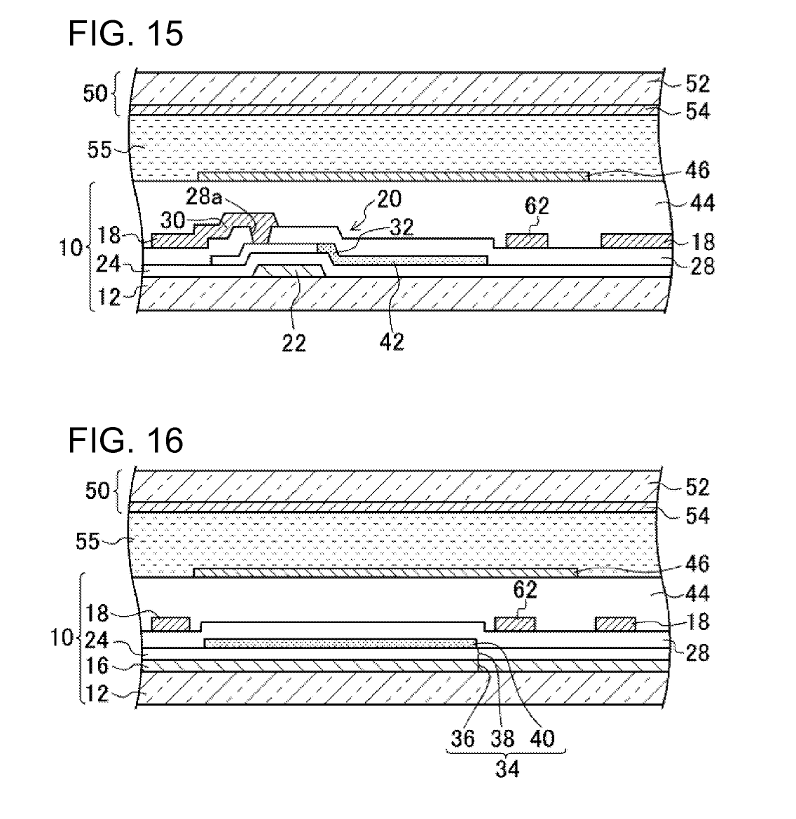

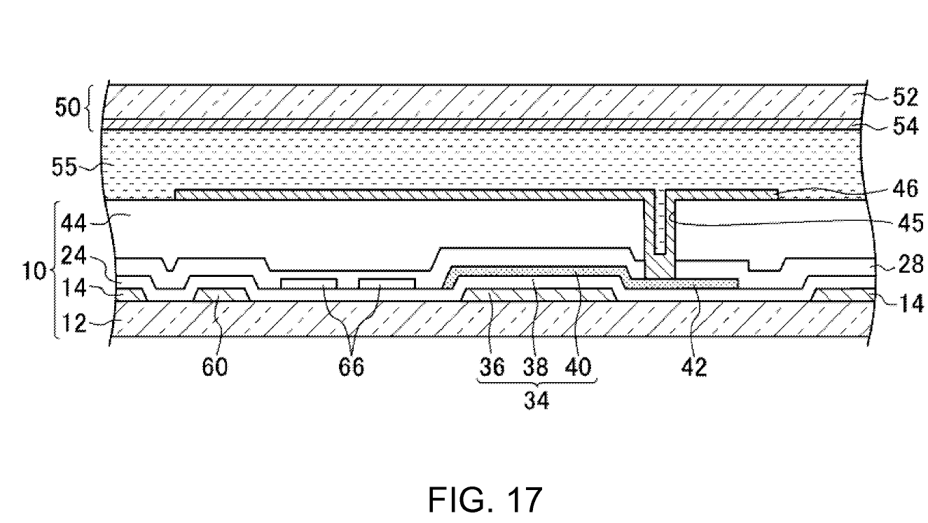

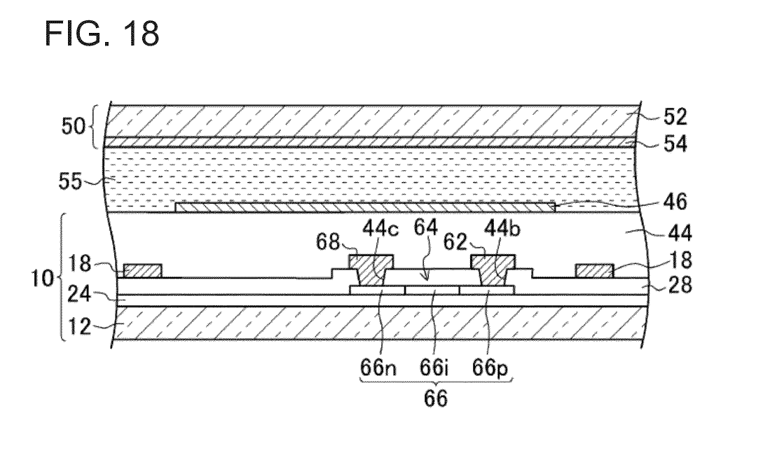

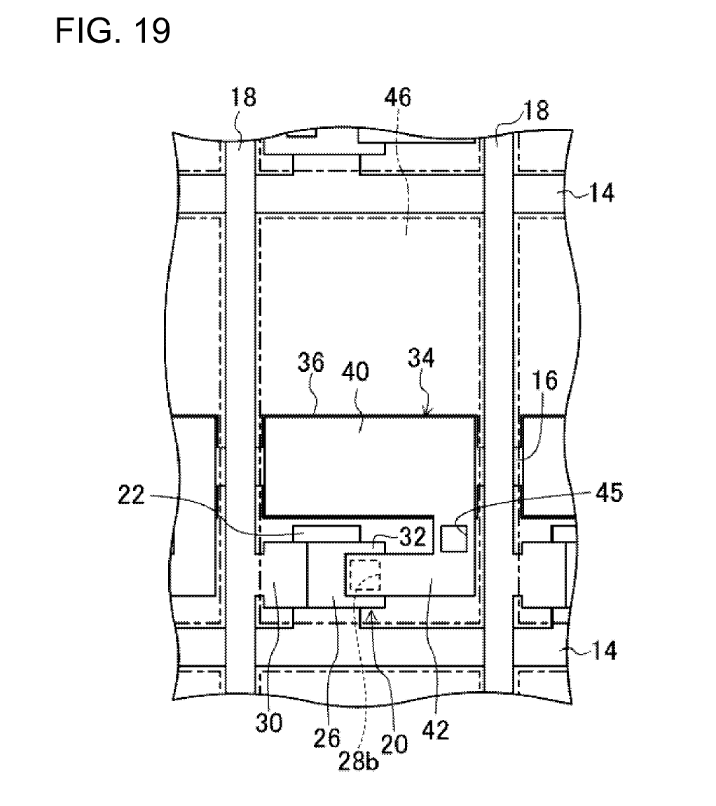

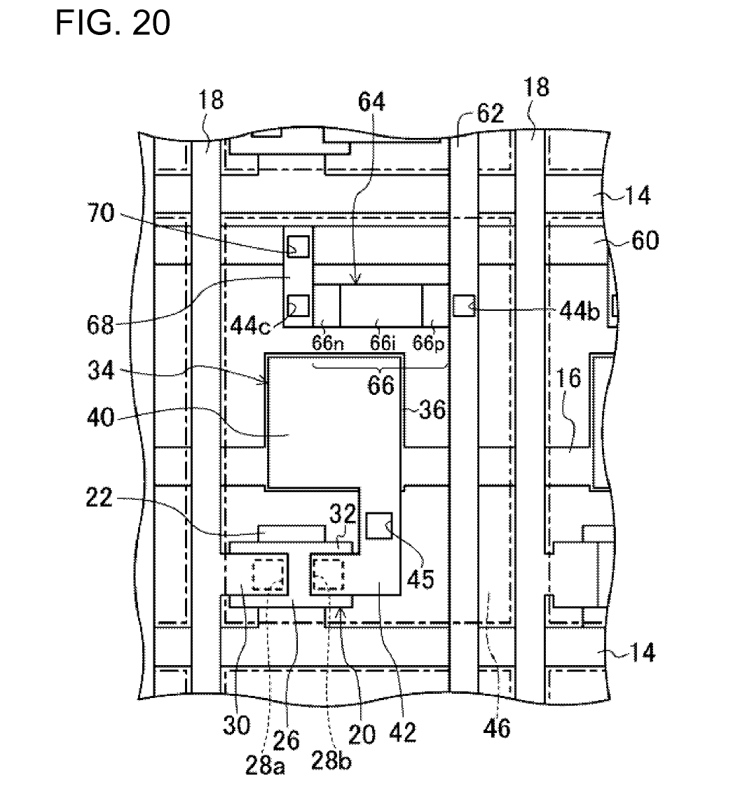

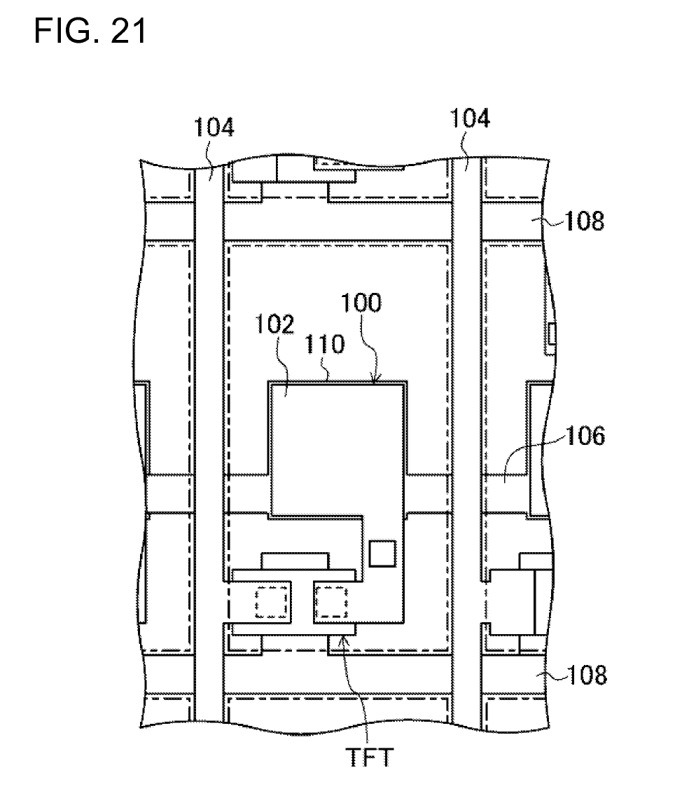

FIG. 1 is a schematic plan view of a liquid crystal display device S according to the present embodiment. FIG. 2 is a schematic cross-sectional view of the liquid crystal display device S along the line II-II in FIG. 1. In FIG. 1, a polarizing plate 59 shown in FIG. 2 is not shown.

<Configuration of the Liquid Crystal Display Device S>

The liquid crystal display device S is provided with a TFT substrate 10 and an opposite substrate 50 disposed to face each other, a frame-shaped sealing member 54 that bonds respective circumferences of the TFT substrate 10 and of the opposite substrate 50, and a liquid crystal layer 55 disposed between the TFT substrate 10 and the opposite substrate 50, being sealed inside the sealing member 54.

The liquid crystal display device S has a display area D and a terminal region 10a. The display area D displays an image on a region where the TFT substrate 10 and the opposite substrate 50 overlaps, which is inside the sealing member 54, i.e., on a region where the liquid crystal layer 55 is provided. The display area D is a rectangular-shaped region, for example, and is made of a plurality of pixels, which are the smallest units of an image, being arranged in a matrix. The terminal region 10a is a portion of the TFT substrate 10 that protrudes from the opposite substrate 50 to an outside of the display area D. Ends of gate wiring lines and source wiring lines, which are not shown but will be described later, are led out to the terminal region 10a to form terminals. Integrated circuit chips, a wiring board, and the like are mounted on the terminal region 10a so as to be connected to the terminals of the respective wiring lines through an anisotropic conductive film (hereinafter referred to as “ACF”) and the like. This way, display signals and the like are supplied from external circuits to the device.

The TFT substrate 10 and the opposite substrate 50 are formed in a rectangular shape, for example. As shown in FIG. 2, alignment films 56 and 57 are formed on respective inner surfaces of the TFT substrate 10 and the opposite substrate 50 that face each other, and polarizing plates 58 and 59 are formed on respective outer surfaces thereof. The liquid crystal layer 55 is made of nematic liquid crystal materials and the like that have electrooptic characteristics.

<Configuration of the TFT Substrate 10>

FIGS. 3 to 6 are schematic views showing a configuration of the TFT substrate 10. FIG. 3 is a plan view showing one pixel in the TFT substrate 10. FIG. 4 is a cross-sectional view of the liquid crystal display device S along the line IV-IV in FIG. 3. FIG. 5 is a cross-sectional view of the liquid crystal display device S along the line V-V in FIG. 3. FIG. 6 is a cross-sectional view of the liquid crystal display device S along the line VI-VI in FIG. 3. In FIGS. 4 to 6, the alignment films 56 and 57 and the polarizing plates 58 and 59 are not shown.

The TFT substrate 10 has an insulating substrate 12 that is a glass substrate or the like as shown in FIGS. 4 to 6. As shown in FIG. 3, the TFT substrate 10 is provided with a plurality of gate wiring lines 14 disposed on the insulating substrate 12 so as to extend in parallel with each other, storage capacitance wiring lines 16 provided to the respective gate wiring lines 14 so as to extend along the respective gate wiring lines 14, and a plurality of source wiring lines 18 disposed so as to extend in parallel with each other in a direction that intersects with the respective gate wiring lines 14 and the respective storage capacitance wiring lines 16, on the display region D. The gate wiring lines 14 and the source wiring lines 18 are arranged to form a grid pattern as a whole to border the respective pixels. The storage capacitance wiring lines 16 extend across the plurality of pixels that are aligned in a direction to which the gate wiring lines 14 extend.

The respective gate wiring lines 14 and the respective storage capacitance wiring lines 16 are covered by a gate insulating film 24 and an insulating film 28 that are laminated in this order as shown in FIGS. 4 to 6. The respective source wiring lines 18 are formed on the insulating film 28. The respective gate wiring lines 14 and the respective storage capacitance wiring lines 16 intersect with the respective source wiring lines 18 having the gate insulating film 24 and the insulating film 28 interposed therebetween, thereby being insulated from each other.

The TFT substrate 10 is further provided with a TFT 20, a storage capacitance element 34, and a pixel electrode 46 (shown with a one-dot chain line in FIG. 3) disposed at each of the intersections of the respective gate wiring lines 14 and the respective source wiring lines 18, i.e., in each pixel.

As shown in FIG. 4, each of the TFTs 20 is provided with a gate electrode 22, the gate insulating film 24 that covers the gate electrode 22, an oxide semiconductor layer 26 that overlaps the gate electrode 22 through the gate insulating film 24, and a source electrode 30 and a drain electrode 32 connected to the oxide semiconductor layer 26, being separated from each other. The gate electrode 22 is a portion of the gate wiring line 14 that protrudes to the upper side in FIG. 3. The gate insulating film 24 is formed on the substantially entire surface of the substrate. The oxide semiconductor layer 26 is made of indium gallium zinc oxide (hereinafter referred to as IGZO)-based metal oxide, for example, and is transparent.

In the present embodiment, the oxide semiconductor layer 26 is made of the IGZO-based metal oxide. Alternatively, the oxide semiconductor layer 26 may be made of other oxide semiconductor such as zinc oxide (ZiO), zinc tin oxide (ZTO), strontium titanate (SrTiO₃), indium oxide (In₂O₃), and copper aluminum oxide (CuAlO₂).

As shown in FIG. 4, each of the TFTs 20 is provided with the insulating film 28 having a contact hole 28a so as to cover the oxide semiconductor layer 26 excluding an area where the source electrode 30 makes contact with the oxide semiconductor layer 26. The source electrode 30 is formed on the insulating film 28 so as to be connected to the oxide semiconductor layer 26 through the contact hole 28a. The source electrode 30 is a portion of the source wiring line 18 that protrudes to the right side in FIG. 3. On the other hand, the drain electrode 32 is formed of a conductor layer portion that is extended from the oxide semiconductor layer 26, and is integrally formed with the oxide semiconductor layer 26.

As shown in FIG. 5, each of the storage capacitance elements 34 has a lower electrode 36 made of a portion of the storage capacitance wiring line 16 and covered by the gate insulating film 24, a dielectric layer 38 made of a portion of the gate insulating film 24 corresponding to the lower electrode 36, and an upper electrode 40 that overlaps the lower electrode 36 having the dielectric layer 38 interposed therebetween. The portion of the storage capacitance wiring line 16 that forms the lower electrode 36 is expanded toward the two gate wiring lines 14 as shown in FIG. 3, and secures a prescribed area for the lower electrode 36. The upper electrode 40 is connected to the drain electrode 32 via a local wiring line section 42 shown in FIG. 3. Also, together with the drain electrode 32 and the local wiring line section 42, the upper electrode 40 is formed of a conductor layer portion that is extended from the oxide semiconductor layer 26, and is therefore integrally formed with the oxide semiconductor layer 26.

As shown in FIG. 5, the insulating film 28 that covers the oxide semiconductor layer 26 is disposed between the upper electrode 40 and the two source wiring lines 18 that sandwich the upper electrode 40. The upper electrode 40 and the source wiring lines 18 are separately formed in respective upper and lower layers having the insulating film 28 interposed therebetween.

The drain electrode 32, the local wiring line section 42, and the upper electrode 40 are formed by processing the oxide semiconductor layer so as to lower a resistance thereof, which will be described later in detail, so that the characteristics of the oxide semiconductor layer change from those of semiconductor to those of conductor. The drain electrode 32, the local wiring line section 42, and the upper electrode 40 are transparent. This way, light is transmitted through the oxide semiconductor layer 26 and also through areas where the drain electrode 32 and the local wiring line section 42 are formed in the respective pixels, thereby increasing an aperture ratio of the respective pixels. Further, because the drain electrode 32 does not extend over the end of the oxide semiconductor layer 26, the drain electrode 32 is not separated by a level difference between the gate insulating film 24 and the oxide semiconductor layer 26. This results in reducing a risk of a wiring problem such as disconnection, thereby improving yield.

As shown in FIGS. 4 to 6, the respective TFTs 20 and the respective storage capacitance elements 34 are covered by an interlayer insulating film 44. On this interlayer insulating film 44, the respective pixel electrodes 46 are formed. As shown in FIG. 6, the interlayer insulating film 44 and the insulating film 28 have a contact hole 45, which reaches the local wiring line section 42, formed in an area corresponding to each local wiring line section 42. The respective pixel electrodes 46 are connected to the local wiring line sections 42 through the contact holes 45. The respective pixel electrodes 46 are formed over the substantially entire pixels so as to cover the TFTs 20 and the storage capacitance elements 34, respectively. This way, a voltage can be applied to the liquid crystal layer 55 on the areas where the TFTs of the respective pixels are formed as described later. As a result, transmittance of light that has passed through areas around the TFTs 20, the oxide semiconductor layer 26, and the drain electrode 32 can be adjusted in the liquid crystal layer 55. This allows the areas where the TFTs 20 are formed to be utilized for display, thereby improving a display quality.

<Configuration of the Opposite Substrate 50>

The opposite substrate 50 is provided with a black matrix arranged in a grid pattern so as to correspond to the gate wiring lines 14 and the source wiring lines 18, color filters of a plurality of colors including red layers, green layers, and blue layers disposed in the respective grids of the black matrix in an orderly manner, the common electrode 54 disposed to cover the black matrix and the respective color filters, and photospacers formed in a columnar shape on the common electrode. These elements are disposed on an insulating substrate 52 that is a glass substrate or the like shown in FIGS. 4 to 6.

<Operation of the Liquid Crystal Display Device S>

In the liquid crystal display device S having the above configuration, when gate signals are sent to the gate electrodes 22 through the gate wiring lines 14, thereby turning ON the TFTs 20 in the respective pixels, source signals are sent to the source electrodes 30 through the source wiring lines 18. As a result, a prescribed electric charge is written in the pixel electrode 46 through the oxide semiconductor layer 26 and the drain electrode 32, and the storage capacitance element 34 is charged with an electric charge that corresponds to this prescribed electric charge. At this time, a potential difference is generated between the respective pixel electrodes 46 on the TFT substrate 10 and the common electrode 54 on the opposite substrate 50, and therefore, a prescribed voltage is applied to the liquid crystal layer 55. When the respective TFTs 20 are turned OFF, storage capacitance formed in the storage capacitance element 34 prevents the voltage written on the corresponding pixel electrodes 46 from being reduced. In the liquid crystal display device S, transmittance at the liquid crystal layer 55 is adjusted by changing an orientation state of liquid crystal molecules in accordance with a size of the voltage applied to the liquid crystal layer 55 in the respective pixels, and as a result, an image is displayed.

Manufacturing Method

Next, a method of manufacturing the liquid crystal display device S and the TFT substrate 10 will be described using an example with reference to FIGS. 7 to 13. FIG. 7 is a cross-sectional view showing a state in which the gate insulating film 24 is deposited in a TFT substrate manufacturing process. FIGS. 8 to 11 are cross-sectional views respectively showing processes of forming the oxide semiconductor layer 26, the drain electrode 32, the local wiring line section 42, and the upper electrode 40 in the TFT substrate manufacturing process. FIGS. 12 and 13 are cross-sectional views showing processes after the source wiring line 18 and the source electrode 30 are formed. The respective figures (a) of FIGS. 7 to 13 show portions that correspond to FIG. 4. The respective figures (b) of FIGS. 7 to 13 show portions that correspond to FIG. 5.

The method of manufacturing the liquid crystal display device S of this embodiment includes the TFT substrate manufacturing process, an opposite substrate manufacturing process, a bonding process, and a mounting process.

<TFT Substrate Manufacturing Process>

First, on the insulating substrate 12 that is a glass substrate or the like prepared in advance, a titanium film (about 30 nm thick, for example), an aluminum film (about 200 nm thick, for example), and a titanium film (about 100 nm thick, for example) are deposited in this order, for example, by sputtering, thereby forming a multilayer metal film. Thereafter, this multilayer metal film is patterned by photolithography, thereby simultaneously forming the gate wiring line 14, the gate electrode 22, the storage capacitance wiring line 16, and the lower electrode 36. Next, on the substrate having the gate wiring line 14, the storage capacitance wiring line 16, and the like formed thereon, a silicon nitride film (about 325 nm thick, for example) and a silicon dioxide film (about 50 nm thick, for example) are deposited in this order by plasma CVD (Chemical Vapor Deposition) method, thereby forming the gate insulating film 24 having a multilayer structure as shown in FIG. 7.

Next, on the substrate having the gate insulating film 24 formed thereon, an IGZO-based oxide semiconductor film 25 is deposited by sputtering as shown in FIG. 8. Thereafter, a photosensitive resin is applied on the oxide semiconductor film 25, and this photosensitive resin film is exposed through a photomask and is thereafter developed, thereby forming a resist pattern 27 on an area where the semiconductor layer 26, the drain electrode 32, the local wiring line section 42 of the TFT 20, and the upper electrode 40 of the storage capacitance element 34 are formed as shown in FIG. 9. Here, by patterning the photosensitive resin film using a multi-tone mask such as a halftone mask, for example, a portion of the resist pattern 27 located in an area where the semiconductor layer 26 of the TFT is to be formed is formed thick, and the other portion of the resist pattern 27 located in an area where the drain electrode 32, the local wiring line section 42, and the upper electrode 40 of the storage capacitance element 34 are to be formed is formed thin.

Next, the oxide semiconductor film 25 is etched and patterned using the resist pattern 27 as a mask and applying oxalic acid solution, for example, thereby forming an oxide semiconductor layer 26′ as shown in FIG. 10. Next, only the thin portion of the resist pattern 27 is removed by ashing such that only the thick portion of the resist pattern 27 remains. Thereafter, a portion of the oxide semiconductor layer 26′ exposed from the resist pattern 27′ is exposed to reducing plasma such as hydrogen plasma, using the remaining resist pattern 27′ as a mask. As a result, as shown in FIG. 11, the oxide semiconductor layer 26′ excluding the area where the semiconductor layer 26 of the TFT 20 is to be formed is reduced, thereby lowering a resistance thereof and changing the characteristics thereof from those of semiconductor to those of conductor. In such a manner, the oxide semiconductor layer 26, the drain electrode 32, the local wiring line section 42, and the upper electrode 40 are formed, and the storage capacitance element 34 is also formed. Thereafter, the remaining resist pattern 27′ is also removed by ashing.

In the present embodiment, the characteristics of the portion of the oxide semiconductor layer 26′ are changed from those of semiconductor to those of conductor by exposing the portion of the oxide semiconductor layer 26′ exposed from the resist pattern 27′ to the reducing plasma. Alternatively, the resistance of the portion of the oxide semiconductor layer 26′ may be lowered by other methods such as ion implantation, laser radiation, and reduction annealing.

Further, on the substrate having the oxide semiconductor layer 26, the drain electrode 32, the local wiring line section 42, and the upper electrode 40 formed thereon, a silicon dioxide film or a TEOS (Tetra Ethyl Ortho Silicate) film, for example, is deposited by plasma CVD method, thereby forming the insulating film 28 (about 150 nm thick, for example). Thereafter, this insulating film 28 is patterned by photolithography, thereby forming the contact hole 28a in the insulating film 28.

Next, on the substrate having the insulating film 28 formed thereon, a titanium film (about 30 nm thick, for example), an aluminum film (about 200 nm thick, for example), and a titanium film (about 100 nm thick, for example) are deposited in this order, for example, by sputtering, thereby forming a multilayer metal film. Thereafter, this multilayer metal film is patterned by photolithography, thereby forming the source wiring lines 18 and the source electrode 30 as shown in FIG. 12.

Thereafter, on the substrate having the source wiring lines 18 and the source electrode 30 formed thereon, a positive type phenol novolac-based photosensitive resin, for example, is applied by spin coating method, and this photosensitive resin film is exposed through a photomask and thereafter developed, thereby forming the interlayer insulating film 44 that has a contact hole 44a. Thereafter, the interlayer insulating film 44 is baked and completed. Next, on this interlayer insulating film 44, an indium tin oxide (hereinafter referred to as ITO) film is deposited by sputtering, and the ITO film is patterned by photolithography, thereby forming the pixel electrode 46 as shown in FIG. 13.

In the manner described above, the TFT substrate 10 can be manufactured.

<Opposite Substrate Manufacturing Process>

First, on an entire surface of the insulating substrate 52 that is a glass substrate or the like, a negative type acrylic photosensitive resin in which particles such as carbon particles, for example, are dispersed is applied by spin coating method or by slit coating method. Next, this photosensitive resin film is patterned by exposure through a photomask and development, and as a result, a black matrix is formed.

Next, on the substrate having the black matrix formed thereon, a negative type acrylic photosensitive resin that is colored red, green, or blue, for example, is applied. This photosensitive resin film is patterned by exposure through a photomask and development, thereby forming colored layers of a selected color (red layers, for example). The same steps are repeated to form colored layers of other two colors (green layers and blue layers, for example), and as a result, the color filter is formed.

Next, on the substrate having the color filter formed thereon, an ITO film, for example, is deposited by sputtering, thereby forming the common electrode 54. Thereafter, on the substrate having the common electrode 54 formed thereon, a positive type phenol novolac-based photosensitive resin is applied by spin coating method. This photosensitive resin film is exposed through a photomask and is thereafter develolped, thereby forming photospacers.

In the manner described above, the opposite substrate 50 can be manufactured.

<Bonding Process>

First, on a surface of the TFT substrate 10, a polyimide resin is applied by printing method, and thereafter, a rubbing treatment is performed as necessary, thereby forming the alignment film 56. Further, on a surface of the opposite substrate 50, a polyimide resin is applied by printing method, and thereafter, a rubbing treatment is performed as necessary, thereby forming the alignment film 57.

Next, the sealing member 54 such as a UV-curable and thermosetting resin is formed in a rectangular frame shape on the opposite substrate 50 having the alignment film 56 formed thereon, using a dispenser or the like. Thereafter, a prescribed amount of liquid crystal materials is dripped inside the sealing member 54 formed on the opposite substrate 50.

Next, the opposite substrate 50 having the liquid crystal materials dripped thereon and the TFT substrate 10 having the alignment film 56 formed thereon are bonded under the reduced pressure. Thereafter, the bonded stacked body is exposed to the atmospheric pressure such that a pressure is applied to the surfaces of the stacked body. Further, UV (UltraViolet) light is radiated on the sealing member 54 formed on the stacked body, thereby temporarily curing the sealing member 54. Thereafter, the sealing member 54 is permanently cured by heating the stacked body, thereby bonding the TFT substrate 10 and the opposite substrate 50.

Next, the polarizing plates 58 and 59 are bonded on the respective outer surfaces of the TFT substrate 10 and the opposite substrate 50 that were bonded to each other.

<Mounting Process>

After the ACF is placed on the terminal region 10a that is part of the stacked body on which the polarizing plates 58 and 59 are bonded on both of the surfaces, integrated circuit chips and a wiring board are thermally compressed on the terminal region through the ACF, thereby mounting the integrated circuit chips and the wiring board on the stacked body.

By performing the processes described above, the liquid crystal display device S can be manufactured.

### Effects of the Present Embodiment

According to this embodiment, the semiconductor layers 26 of the respective TFTs 20 are made of oxide semiconductor, and the upper electrodes 40 of the respective storage capacitance elements 34 and the source wiring lines 18 that respectively sandwich the upper electrodes 40 are separately formed in the respective upper and lower layers having the insulating film 28 interposed therebetween, by taking advantage of characteristics of the oxide semiconductor layer 26. Therefore, a margin does not need to be made between the upper electrode 40 and the source wiring lines 18 disposed on both sides thereof. Consequently, the upper electrode 40 can be expanded toward the two source wiring lines 18. This way, the portions of the storage capacitance wiring lines 16 near the source wiring lines 18 can be utilized as the lower electrode 36, thereby securing a large area where the lower electrode 36 and the upper electrode 40 face each other along the storage capacitance wiring lines 16. Therefore, the portions of the electrodes 36 and 40 on the sides close to the gate wiring lines 14 can be made smaller. As a result, the aperture ratio of the respective pixels can be improved, and an area between the storage capacitance element 34 and the gate wiring lines 14 can be designed to be wider. Therefore, the TFTs 20 having excellent characteristics can be achieved by using oxide semiconductor, and a degree of freedom in circuit design can be increased by improving the aperture ratio of the respective pixels. According to this configuration, it becomes easier to appropriately build additional various circuits such as photosensor circuits and pixel memory circuits into the respective pixels, thereby achieving a high-function display device.

### Modification Example

FIGS. 14 to 18 show a configuration of the TFT substrate 10 of the above-mentioned embodiment in which photosensor circuits are built into the respective pixels. FIG. 14 is a schematic plan view showing one pixel in the TFT substrate 10 in this modification example. FIG. 15 is a cross-sectional view of the liquid crystal display device S along the line XV-XV in FIG. 14. FIG. 16 is a cross-sectional view of the liquid crystal display device S along the line XVI-XVI in FIG. 14. FIG. 17 is a cross-sectional view of the liquid crystal display device S along the line XVII-XVII in FIG. 14. FIG. 18 is a cross-sectional view of the liquid crystal display device S along the line XVIII-XVIII in FIG. 14. FIGS. 15 to 17 respectively show portions corresponding to FIGS. 4 to 6 that were referred to in the above-mentioned embodiment.

As shown in FIG. 14, the TFT substrate 10 of this modification example is provided with first sensor signal wiring lines 60 provided to the respective gate wiring lines 14 so as to extend along the respective gate wiring lines 14 and second sensor signal wiring lines 62 provided to the respective source wiring lines 18 so as to extend along the respective source wiring lines 18.

As shown in FIG. 17, the respective first sensor signal wiring lines 60 are formed on the insulating substrate 12 together with the respective gate wiring lines 14 and the respective storage capacitance wiring lines 16, and are covered by the gate insulating film 24 and the insulating film 28. As shown in FIGS. 15 and 16, the respective second sensor signal wiring lines 62 are formed on the insulating film 28 together with the respective source wiring lines 18. The respective gate wiring lines 14, the respective storage capacitance wiring lines 16, and the respective first sensor signal wiring lines 60 intersect with the respective second sensor signal wiring lines 62 having the gate insulating film 24 and the insulating film 28 interposed therebetween, thereby being insulated from each other.

In each pixel, two photosensor elements 64 are provided in parallel between the storage capacitance element 34 and the first sensor signal wiring line 60.

As shown in FIGS. 14, 17, and 18, each of the photosensor elements 64 is PIN (P Intrinsic N) diodes respectively provided with a semiconductor layer 66, and is disposed on the gate insulating film 24 so as to extend along the first sensor signal wiring line 60. Each of the respective semiconductor layers 66 of these photosensor elements 64 is made of amorphous silicon, for example, and has an intrinsic region 66i, a P-type impurity region 66p formed on one side (the right side in FIG. 18) of the intrinsic region 66i, and an N-type impurity region 66n formed on the other side (the left side in FIG. 18) of the intrinsic region 66i.

In the insulating film 28 that covers the respective semiconductor layers 66, contact holes 44b and 44c are formed on areas corresponding to the P-type impurity region 66p and the N-type impurity region 66n. The P-type impurity region 66p is connected to the second sensor signal wiring line 62 through the contact holes 44b, and the N-type impurity region 66n is connected to a sensor signal connection wiring line 68 through the contact holes 44c. The sensor signal connection wiring line 68 is disposed on the insulating film 28 so as to extend in parallel with the second sensor signal wiring line 62, extending from areas corresponding to the N-type impurity regions 66n of the respective semiconductor layers 66 to an area corresponding to the first sensor signal wiring line 60. The sensor signal connection wiring line 68 is connected to the first sensor signal wiring line 60 through a contact hole 70 formed in the gate insulating film 24 and in the insulating film 28 on an area corresponding to the first sensor signal wiring line 60.

In each of the photosensor elements 64 having the above configuration, when light enters the semiconductor layer 66, holes are formed in the P-type impurity region 66p and electrons are gathered in the N-type impurity region 66n, thereby generating a voltage. By detecting this voltage using external circuits through the first and second sensor signal wiring lines 60 and 62, a state of the light entering the respective pixels is detected.

In manufacturing the TFT substrate 10 of this modification example, the respective first sensor signal wiring lines 60 are formed of the same film as that of the gate wiring lines 14 when forming the gate wiring lines 14. The respective second sensor signal wiring lines 62 are formed of the same film as that of the source wiring lines 18 when forming the source wiring lines 18.

The respective semiconductor layers 66 are formed by depositing an amorphous silicon film (about 50 nm thick, for example) on the gate insulating film 24 that has been formed, and by patterning the amorphous silicon film by photolithography. Thereafter, a P-type impurity and an N-type impurity are implanted in this order in part of the respective semiconductor layers 66, thereby forming the P-type impurity region 66p and the N-type impurity region 66n. This way, the respective photosensor elements 64 are formed.

More specifically, after the respective semiconductor layers 66 are formed, a photosensitive resin is applied, exposed, and developed, thereby forming a resist pattern having openings such that the P-type impurity regions 66p formed in the respective semiconductor layers 66 are exposed from the openings. Next, a P-type impurity such as bolon (B) is implanted in the portions of the respective semiconductor layers 66 exposed from the openings in the resist pattern, using the resist pattern as a mask, thereby forming the P-type impurity regions 66p, and thereafter, the resist pattern is removed. Next, the photosensitive resin is applied, exposed, and developed, thereby forming a resist pattern having openings such that the N-type impurity regions 66n formed in the respective semiconductor layers 66 are exposed from the openings. Thereafter, an N-type impurity such as phosphorous (P) is implanted in the portions of the respective semiconductor layers 66 exposed from the openings in the resist pattern, using the resist pattern as a mask, thereby forming the N-type impurity regions 66n. Thereafter, the resist pattern is removed.

Other components are formed in the same manner as those described in the above-mentioned embodiment.

FIG. 20 shows a configuration of one pixel in a case where photosensor circuits are built in respective pixels in a conventional TFT substrate for comparison. In FIG. 20, the same components as those in FIG. 14 are given the same reference characters, and the detailed description thereof will not be repeated for convenience. The reference character 28a in FIG. 20 represents a contact hole formed in the insulating film 28 in the same manner as the contact hole 28b.

In case of having the photosensor circuits built in the respective pixels in the conventional TFT substrate, because a space between the storage capacitance element 34 and the gate wiring line 14 shown in the upper side of FIG. 20 is narrow, only one photosensor element, which corresponds to the photosensor element 64 in the TFT substrate 10 described in the above-mentioned modification example, can be formed in each of the pixels.

On the other hand, according to the TFT substrate 10 of this modification example, two photosensor elements 64 can be disposed in each of the pixels. This results in doubling the area where light is detected, thereby increasing an accuracy of detection of light entering the respective pixels. Therefore, when the photosensor elements 64 in the respective pixels are utilized as position detection sensors, for example, the high-function liquid crystal display device S having a highly accurate touch panel function can be achieved.

In this modification example, the photosensor circuits having the first and second sensor signal wiring lines 60 and 62, the sensor signal connection wiring lines 68, and the photosensor elements 64 in to the respective pixles therein are described as an example. In addition, amplifier elements and capacitor elements may be further built in to the respective pixels. Further, instead of the photosensor circuits, other circuits such as pixel memory circuits and driver control circuits may be built in to the respective pixels.

### Another Embodiment

FIG. 19 is a schematic plan view showing a configuration of each pixel in the TFT substrate 10 according to another embodiment.

In the above-mentioned embodiment, the upper electrode 40 is formed of the conductor layer portion that is extended from the oxide semiconductor layer 26 and that has a lowered resistance, and is integrally formed with the oxide semiconductor layer 26. Further, the two source wiring lines 18 that sandwich the upper electrode 40 are formed on the insulating film 28 in each of the pixels. However, the present invention is not limited to such. As shown in FIG. 19, the upper electrode 40 may be formed on the insulating film 28 and connected to the oxide semiconductor layer 26 through the contact hole 28b that was formed in the insulating film 28. Also, together with the source electrode 30 in the respective pixels, the two source wiring lines 18 may be formed of the conductor layer portions that are extended from the oxide semiconductor layers 26 and that have a lowered resistance, and may be integrally formed with the oxide semiconductor layers 26, respectively.

With this configuration, the upper electrode 40 on the respective storage capacitance element 34 and the two source wiring lines 18 that sandwich the upper electrode 40 are separately formed in the respective upper and lower layers having the insulating film 28 interposed therebetween. Therefore, a margin does not need to be made between the upper electrode 40 and the two source wiring lines 18, and the upper electrode 40 can be formed larger toward the respective source wiring lines 18 in the same manner as the above-mentioned embodiment. As a result, the TFTs 20 having the excellent characteristics can be achieved by using the oxide semiconductor, and a degree of freedom in circuit design can be increased by improving the aperture ratio of the respective pixels.

Preferred embodiments of the present invention have been described above, but the technical scope of the present invention is not limited to the scope of the above embodiments. It is apparent to those skilled in the art that the above embodiments are illustrative and the combinations of respective components and the combinations of the respective processes can be further modified variously, and that such modification examples are included in the scope of the present invention.

In the above-mentioned embodiment, for example, the transmissive liquid crystal display device S was described as an example. Alternatively, the TFT substrate 10 of the present invention can be also applied to a reflective liquid crystal display device and a transflective liquid crystal display device. Further, the TFT substrate 10 of the present invention can be applied not only to the liquid crystal display device, but also to other display devices having storage capacitance elements between the display wiring lines in the respective pixels, such as an organic EL (Electro Luminescence) display device.

### INDUSTRIAL APPLICABILITY

As described above, the present invention is useful for a TFT substrate and a liquid crystal display device provided with the same. The present invention is particularly suitable for a TFT substrate that is sought to have TFTs achieving excellent characteristics by using oxide semiconductor and to have an improved aperture ratio in respective pixels such that a degree of freedom in the circuit design is increased, and for a liquid crystal display device provided with the TFT substrate.

### DESCRIPTION OF REFERENCE CHARACTERS

S liquid crystal display device
10 TFT substrate (thin-film transistor substrate)
14 gate wiring line
16 storage capacitance wiring line
18 source wiring line
20 TFT (thin-film transistor)
22 gate electrode
24 gate insulating film
26 oxide semiconductor layer
28a insulating film
28a contact hole
30 source electrode
32 drain electrode
34 storage capacitance element
36 lower electrode
38 dielectric layer
40 upper electrode
42 local wiring line section
44 interlayer insulating film
46 contact hole
50 pixel electrode
55 opposite substrate liquid crystal layer

1. A thin-film transistor substrate, comprising:
a plurality of gate wiring lines that extend in parallel with each other;
storage capacitance wiring lines that are provided to the respective gate wiring lines and that extend along the respective gate wiring lines;
a plurality of source wiring lines that extend in parallel with each other so as to intersect with the respective gate wiring lines and the respective storage capacitance wiring lines; and
a thin-film transistor, a storage capacitance element, and a pixel electrode that are provided for each of intersections of the respective gate wiring lines and the respective source wiring lines,
wherein a plurality of pixels, each of which includes the thin-film transistor, the storage capacitance element, and the pixel electrode, are defined by the respective gate wiring lines and the respective source wiring lines
wherein, in each of the pixels,
the thin-film transistor comprises: a gate electrode connected to the gate wiring line; a gate insulating film that covers the gate electrode; an oxide semiconductor layer that overlaps the gate electrode through the gate insulating film; a source electrode that is connected to one side of the oxide semiconductor layer and that is connected to the source wiring line; and a drain electrode that is connected to the other side of the oxide semiconductor layer and that is connected to the pixel electrode, the drain electrode being separated from the source electrode, and
the storage capacitance element comprises: a lower electrode that is connected to the storage capacitance wiring line and that is covered by the gate insulating film; a dielectric layer that is made of a portion of the gate insulating film corresponding to the lower electrode; and an upper electrode that is extended from the drain electrode and that is disposed between the source wiring lines adjacent to each other, the upper electrode overlapping the lower electrode through the dielectric layer, and
wherein, in each of the pixels, an insulating film that covers is disposed to cover the oxide semiconductor layer; one of the upper electrode and the source wiring line is formed of a conductor layer portion that is extended from the oxide semiconductor layer and that has a lowered resistance, and is thereby integrally formed with the oxide semiconductor layer; and the other of the upper electrode and the source wiring line is formed on the insulating film, and is connected to the oxide semiconductor layer through a contact hole formed in the insulating film.

2. The thin-film transistor substrate according to claim 1,
wherein, in each of the pixels, the upper electrode is led out to an area corresponding to the lower electrode through the drain electrode and a local wiring line section that are formed of a conductor layer portion extended from the oxide semiconductor layer, the conductor layer portion having a lowered resistance in a same manner as the upper electrode, and the pair of source wiring lines are disposed on the insulating film, and
wherein the respective oxide semiconductor layers, the respective local wiring line sections, and the respective upper electrodes are transparent.

3. The thin-film transistor substrate according to claim 2,
wherein the respective thin-film transistors are covered by an interlayer insulating film, and
wherein each of the pixel electrodes is formed on the interlayer insulating film so as to overlap the thin-film transistor, and is electrically connected to the drain electrode through a contact hole formed in the interlayer insulating film and in the insulating film.

4. The thin-film transistor substrate according to claim 1,
wherein the respective oxide semiconductor layers are formed of indium gallium zinc oxide-based metal oxide.

5. A liquid crystal display device, comprising:
the thin-film transistor substrate according to claim 1;
an opposite substrate disposed so as to face the thin-film transistor substrate; and
a liquid crystal layer disposed between the thin-film transistor substrate and the opposite substrate.
